(19) United States
(12) Patent Application Publication
(10) Pub. No.: US 2020/0106446 A1
(43) Pub. Date: Apr. 2, 2020

(54) TEMPERATURE-COMPENSATED FREE-RUNNING OSCILLATOR

(71) Applicant: QUALCOMM Incorporated, San Diego, CA (US)

(72) Inventors: Shyam SIVAKUMAR, Mountain View, CA (US); Kevin Jia-Nong WANG, Poway, CA (US); Anish CHIVUKULA, San Diego, CA (US)

(21) Appl. No.: 16/452,273

(22) Filed: Jun. 25, 2019

Related U.S. Application Data
(60) Provisional application No. 62/738,636, filed on Sep. 28, 2018.

(51) Int. Cl. H03L 1/02; H03B 5/32; G06F 1/06

(52) U.S. Cl. CPC H03L 1/02; G06F 1/06; H03B 5/32

(57) ABSTRACT

This disclosure provides a method and apparatus for a temperature-compensated oscillator. In some example implementations, the temperature-compensated oscillator may include a first oscillator, a second oscillator, and a temperature compensation block. The first oscillator may generate a first periodic clock signal and the second oscillator may generate a second periodic clock signal. The temperature-compensating block may generate a compensation signal based on the first period clock signal and the second periodic clock signal.

### CROSS-REFERENCE TO RELATED APPLICATION

This application claims the benefit of co-pending and commonly owned U.S. Provisional Patent Application No. 62/738,636 entitled “TEMPERATURE COMPENSATED FREE-RUNNING OSCILLATOR” filed on Sep. 28, 2018, the entirety of which is hereby incorporated by reference.

### TECHNICAL FIELD

This disclosure relates generally to oscillators, and more specifically to temperature-compensated, free-running oscillators.

### DESCRIPTION OF THE RELATED TECHNOLOGY

Free-running oscillators may be used in a variety of electronic devices to provide one or more clock signals. In some uses, the clock signals may control digital circuits within the electronic device. In some other uses, the clock signals may affect the transmission and/or reception of communication signals. Accuracy of the clock signals may affect the functionality and operation of the digital circuits. For example, the accuracy of the clock signal may affect proper encoding, decoding, modulation, and/or demodulation of the communication signals.

Extremely accurate clock signals may be provided by crystal-based oscillators. A crystal-based oscillator can provide a periodic clock signal with a very low error rate (on the order of 5 or less parts-per-million (ppm) error). While being accurate and having a very low frequency drift due to temperature changes, crystal-based oscillators may consume significantly more power than other types of oscillators, such as on-chip, free-running oscillators. Increased power consumption may adversely affect battery life of, for example, mobile electronic devices. On-chip free-running oscillators, however, may have less frequency accuracy and frequency stability compared to crystal-based oscillators.

Thus, there is a need to improve free-running oscillator accuracy while reducing a reliance on crystal-based oscillators.

### SUMMARY

The systems, methods and devices of this disclosure each have several innovative aspects, no single one of which is solely responsible for the desirable attributes disclosed herein.

One innovative aspect of the subject matter described in this disclosure can be implemented as a temperature-compensated oscillator. The temperature-compensated oscillator may include a first on-chip oscillator configured to generate a first periodic clock signal and a second on-chip oscillator configured to generate a second periodic clock signal. The temperature-compensated oscillator may also include a temperature compensation block configured to configured to generate a compensation signal based on the first periodic clock signal and the second periodic clock signal.

Another innovative aspect of the subject matter described in this disclosure can be implemented as a temperature-compensated oscillator. The temperature-compensated oscillator can include a means for generating a first periodic clock signal via a first on-chip oscillator, a means for generating a first periodic clock signal via a first on-chip oscillator, and a means for generating a compensation signal based on the first periodic clock signal and the second periodic clock signal.

Another innovative aspect of the subject matter described in this disclosure may be implemented as a method comprising generating, by a first on-chip oscillator, a first periodic clock signal and generating, by a second on-chip oscillator, a second periodic clock signal. The method may also include generating, by a temperature compensation block, a compensation signal based on the first periodic clock signal and the second periodic clock signal.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

Aspects of the present disclosure are illustrated by way of example, and not by way of limitation, in the figures of the accompanying drawings and in which like reference numerals refer to similar elements.

FIG. 1 shows a block diagram of an example communication system.

FIG. 2 shows a simplified block diagram of an example implementation of the temperature-compensated oscillator of FIG. 1.

FIG. 3A shows a graph depicting example temperature dependence relationships of the first oscillator and the second oscillator of FIG. 2.

FIG. 3B shows a graph depicting other example temperature-frequency relationships of the first oscillator and the second oscillator of FIG. 2.

FIG. 4A is a block diagram of one embodiment of a modulus generator.

FIG. 4B is a block diagram of another embodiment of a modulus generator.

FIG. 5 is a block diagram of one embodiment of an output block.

FIG. 6 is a flowchart depicting an example operation for operating the temperature-compensated oscillator of FIGS. 1 and 2.

FIG. 7 shows a block diagram of an example wireless device.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, system or network. Such systems or networks are capable of transmitting and receiving RF signals. The transmission and reception of the signals may be according to any of the IEEE 802.16 standards, or any of the IEEE 802.11 standards, the Bluetooth® standard, code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless, cellular or internet of things (IOT) network, such as a system utilizing 3G, 4G or 5G, or further implementations thereof, technology.

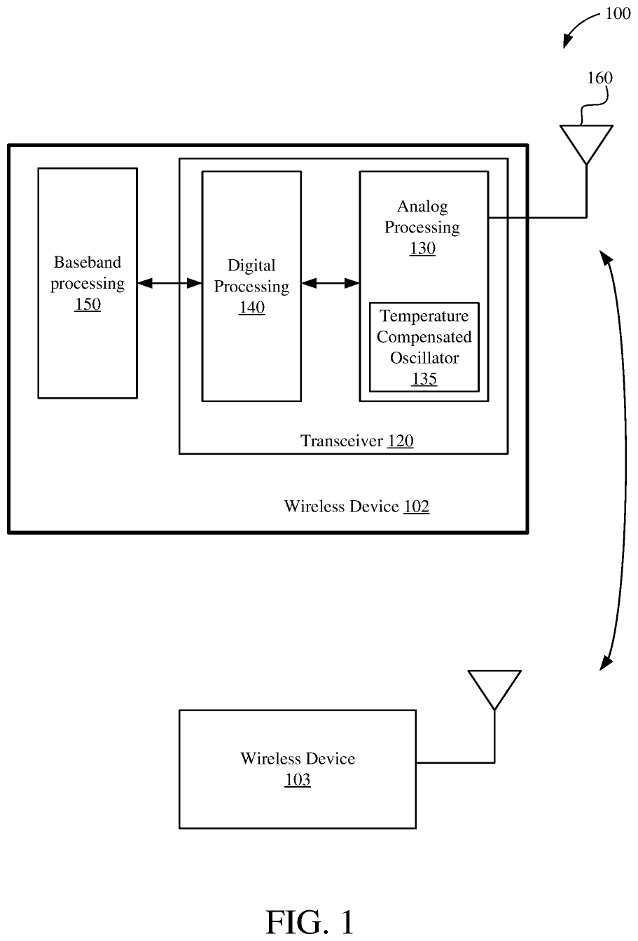

FIG. 1 shows a block diagram of an example communication system 100. The communication system 100 may be a wireless system and may include wireless device 102 and wireless device 103. Although only two wireless devices 102 and 103 are shown for simplicity, the communication system 100 may include any number of wireless devices. In other embodiments, the communication system 100 may be a wired system and may include wired devices coupled to a wire or cable (not shown for simplicity). In still other embodiments, the communication system 100 may be a hybrid system and may include both wireless and wired communication devices. In some implementations, the wireless device 102 may be referred to as a user equipment (UE), a subscriber station, a mobile unit, a subscriber unit, a wireless unit, a remote unit, a mobile device, a wireless device, a wireless communications device, a base station, a remote device, a mobile subscriber station, an access terminal, an access point, a mobile terminal, a wireless terminal, a remote terminal, a handset, a user agent, a mobile client, a client, or some other suitable terminology

The wireless device 102 may include a transceiver 120, a baseband processing unit 150, and an antenna 160. Although not shown for simplicity, wireless device 102 may include a plurality of antennas. For example, the wireless device 102 may include n antennas to enable multiple-input (MI) and/or multiple-output (MO) transmissions, and/or carrier aggregation. Thus, in some example implementations, the communication system 100 may correspond to a multiple-input multiple-output (MIMO) wireless network and may support single-user MIMO (SU-MIMO) and multi-user (MU-MIMO) communications. Baseband processing unit 150 may provide data to be transmitted to and/or receive data from one or more other devices via transceiver 120 and antenna 160. For example, baseband processing unit 150 may encode and/or decode the communication data for transmission and/or reception by transceiver 120.

The wireless devices 102 and 103 may communicate by transmitting and receiving wireless communication signals via a wireless medium. The wireless medium, which may be divided into a number of channels, may facilitate wireless communications via Wi-Fi signals (such as according to the IEEE 802.11 standards), via Bluetooth signals (such as according to the IEEE 802.15 standards), via cellular protocols including CDMA, TDMA, GSM, EDGE, 3G, 4G or other implementations of LTE technology, 5G, or any suitable wireless communication protocol.

Transceiver 120 may include a digital processing unit 140 coupled to an analog processing unit 130. Transceiver 120 may receive the communication data from and provide the communication data to baseband processing unit 150 via digital processing unit 140 and analog processing unit 130. In some embodiments, the communication data may be processed according to a wireless communication protocol such as Wi-Fi, BLUETOOTH, near-field communication, Zig-Bee, cellular, or any other feasible wireless communication protocol. In other embodiments, the communication data may be processed according to a wired protocol such as an Ethernet, Powerline Communication, or any other feasible wired communication protocol. In still other embodiments, the communication data may be processed according to both a wireless and a wired communication protocol.

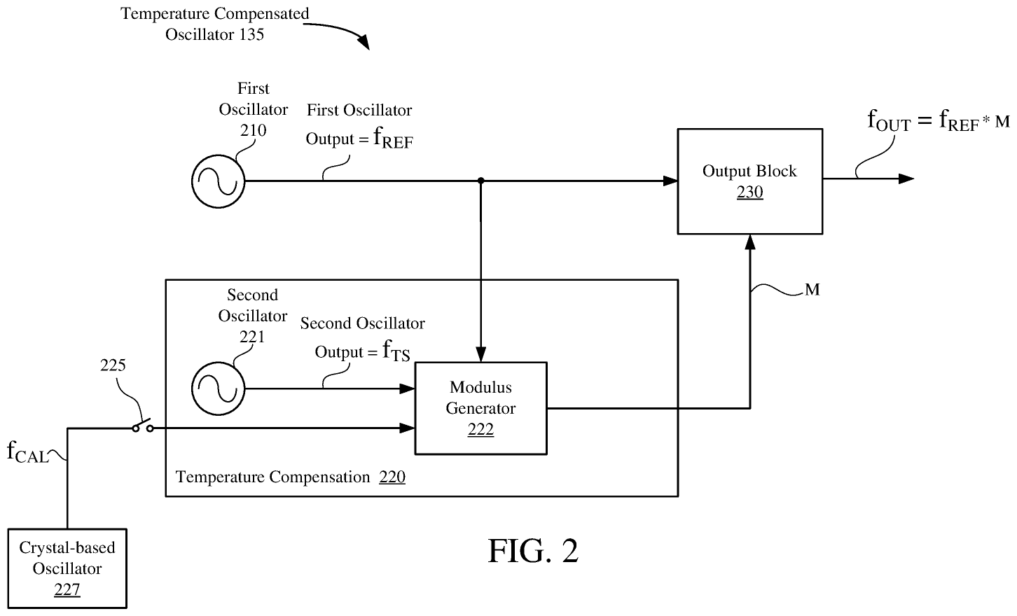

In some example implementations, the digital processing unit 140 may transform the communication data by, for example, performing a Fast Fourier Transform or an Inverse Fast Fourier Transform on the communication data signals. The analog processing unit 130 may modulate and/or demodulate the communication data according to a selected communication protocol. The analog processing unit 130 may include a temperature-compensated oscillator (TCO) 135 to generate clock signals that may be used for data modulation/demodulation. In some implementations, all or part of the TCO 135 may be included in the digital processing unit 140 and/or other units or modules not shown here. Inclusion of the TCO 135 in the analog processing unit 130 does not imply that the TCO 135 is wholly or partially analog, but rather illustrates one possible association between units of the wireless device 102 and the TCO 135. Operation of the TCO 135 is described in more detail below in conjunction with FIGS. 2-7. The wireless device 103 may include a transceiver and a baseband processing unit (not shown for simplicity) and one or more antennas similar to those depicted in wireless device 102.

FIG. 2 shows a simplified block diagram of an example implementation of the TCO 135 of FIG. 1. The TCO 135 may include a first oscillator 210, a temperature compensation block 220, and an output block 230. In some implementations, the TCO 135 may be implemented “on-chip” meaning that the TCO 135 may wholly or substantially be implemented on or within a single integrated circuit. The TCO 135 may include one or more circuits to implement the first oscillator 210, the temperature compensation block 220, and the output block 230. The first oscillator 210 may be a first temperature-dependent, free-running oscillator or oscillator circuit generating a first periodic clock signal, also referred to herein as a first oscillator output signal f_{REF}. Persons having skill in the art will recognize the term “free-running” to describe a device, such as an oscillator, whose output is substantially uncontrolled. A free-running oscillator also may be said to be running “open loop” having no control signals to feedback, regulate or otherwise control the oscillator output frequency or period.

The output block 230 may receive the first oscillator output signal f_{REF}, and a modulus signal M, also referred to herein as a compensation value M, from the temperature compensation block 220. The output block 230 may generate a TCO output signal f_{OUT} based on the first oscillator output signal f_{REF} and the compensation value M. In one example implementation, a frequency of the TCO output signal f_{OUT} may be expressed as the product of a frequency of first oscillator output signal f_{REF} and the compensation value M.

f_{OUT}=f_{REF}*M (eq. 1)

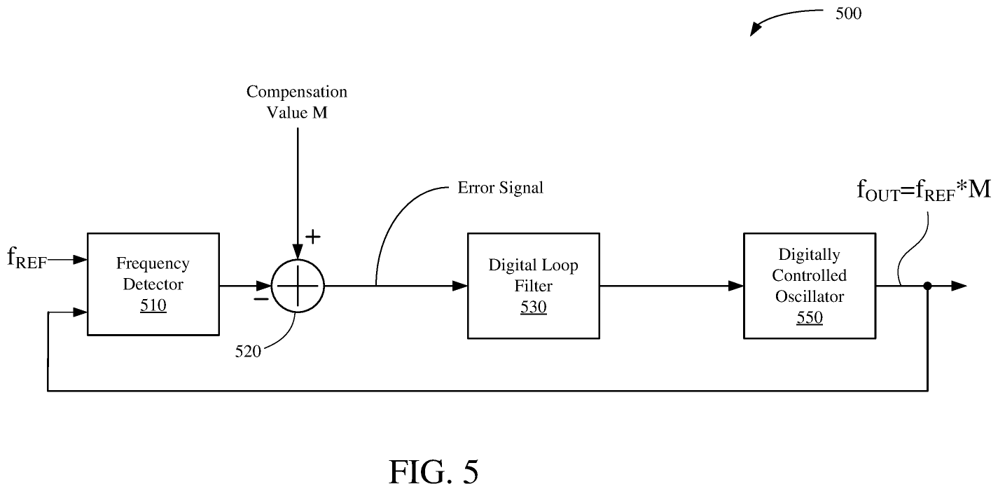

Thus, in some implementations, the compensation signal M may be an adjustment signal to adjust the TCO output signal via the output block 230. Additionally, the output block 230 may include one or more circuits to generate the TCO output signal f_{OUT} based on the first oscillator output signal f_{REF} and the compensation value M. The output block 230 is described in more detail below with respect to FIG. 5.

In one embodiment, the temperature compensation block 220 may generate the compensation value M to correct for temperature drift in the first oscillator 210 output signal f_{REF}. Thus, the compensation value M may be a temperature-dependent compensation signal. The temperature compensation block 220 may enable the TCO 135 to provide a relatively constant TCO output signal f_{OUT} despite changes in temperature. Returning to the example of FIG. 2, if a change in temperature causes the first oscillator 210 to generate a faster (higher frequency) output signal f_{REF} than desired, then the temperature compensation block 220 may generate a smaller compensation value M to enable the output block 230 to generate a slower (as compared to f_{REF}) TCO output signal f_{OUT}. Similarly, if a change in temperature causes the first oscillator 210 to generate a slower (lower frequency) output signal f_{REF} than desired, then the temperature compensation block 220 may generate a larger compensation value M to enable the output block 230 to generate a faster (as compared to f_{REF}) TCO output signal f_{OUT}. Thus, the temperature compensation block 220 may enable temperature compensation of the TCO output signal f_{OUT}.

The temperature compensation block 220 may include a second oscillator 221 and a modulus generator 222. The second oscillator 221 may be a second temperature-dependent, free-running oscillator or oscillator circuit and may generate a second periodic clock signal, also referred to herein as a second oscillator output signal f_{TS}. The second oscillator 221 may have a different temperature-frequency relationship compared to the first oscillator 210.

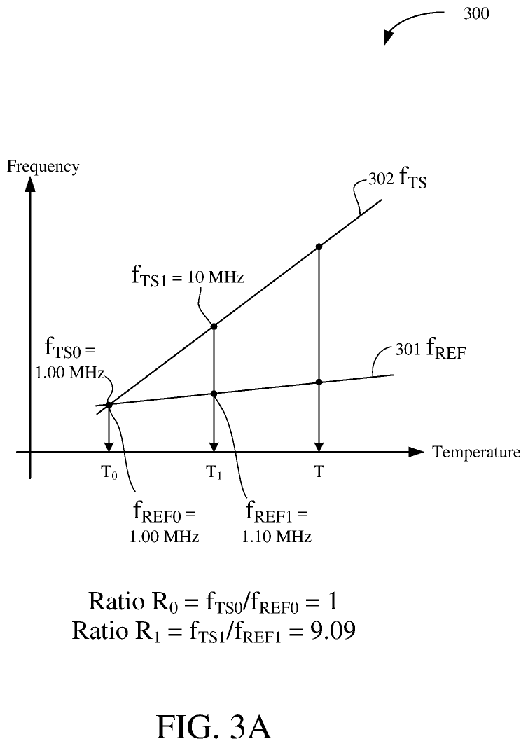

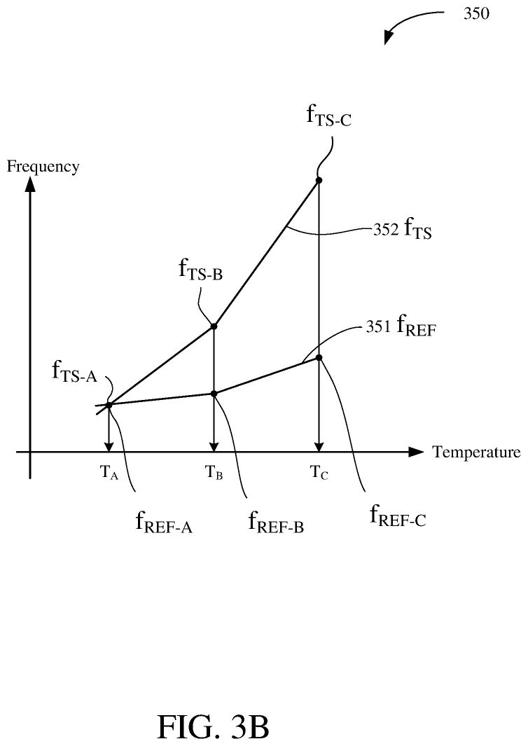

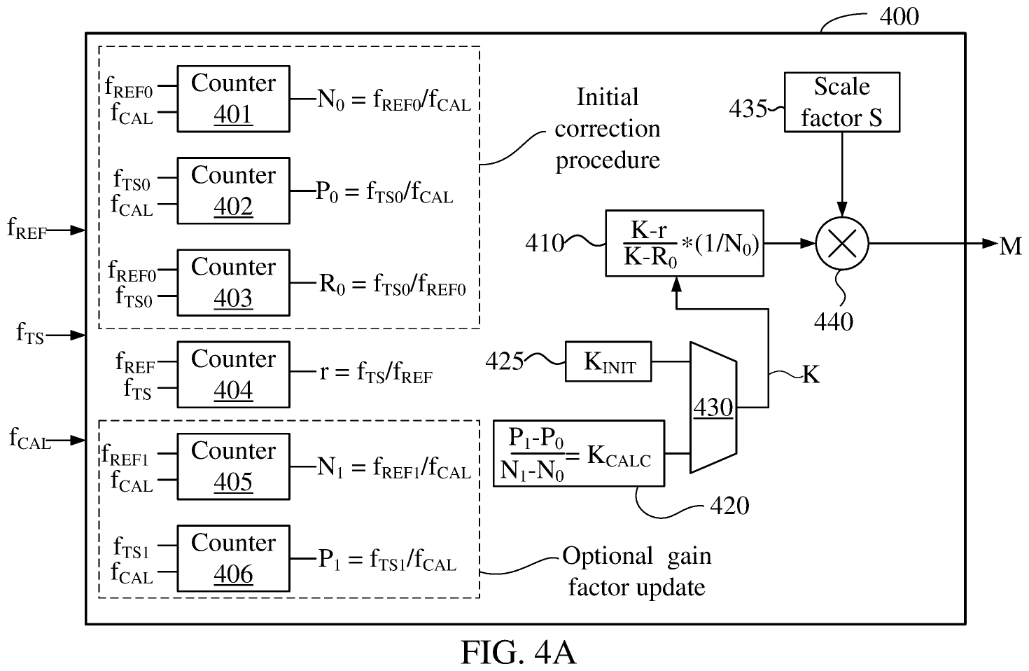

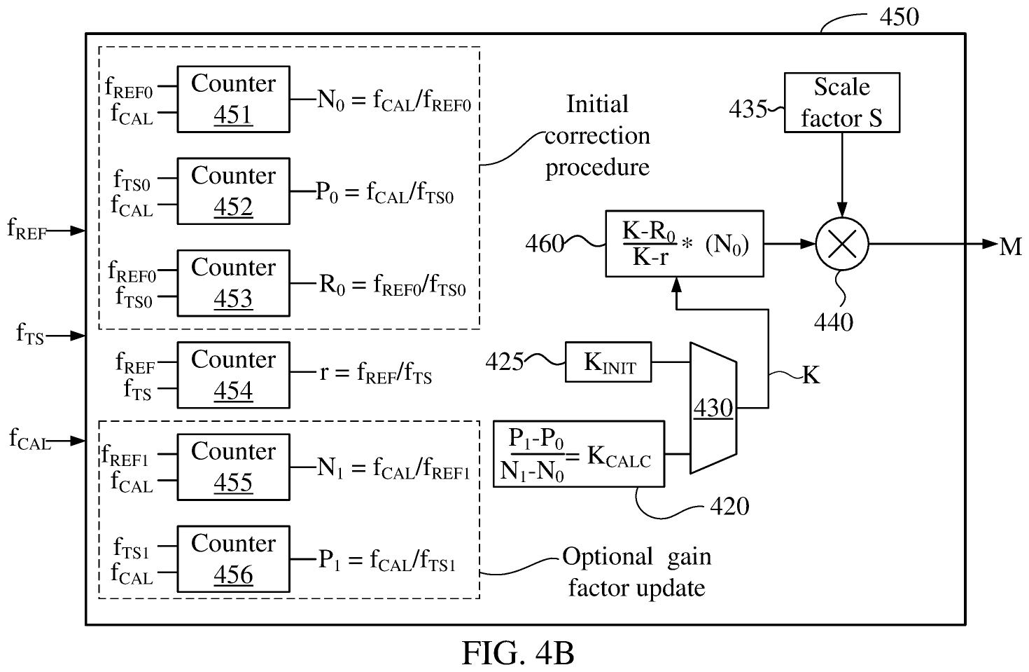

In some implementations, the temperature compensation block 220 may generate the compensation value M without directly measuring the temperature. For example, the compensation value M may be generated, at least in part, by determining a ratio of output frequencies of the first oscillator 210 and the second oscillator 221. In one example implementation, the modulus generator 222 may receive the first oscillator output signal f_{REF} and the second oscillator output signal f_{TS} and may generate the compensation value M based on a ratio of the first oscillator output signal f_{REF} to the second oscillator output signal f_{TS}. Thus, the modulus generator 222 may include one or more circuits to compare the first oscillator output signal f_{REF} to the second oscillator output signal f_{TS}. Determining the compensation value M is described in more detail below in conjunction with FIGS. 3A, 3B, 4A, and 4B.

In some implementations, the temperature compensation block 220 may receive a calibration signal f_{CAL} from an “off-chip” crystal-based oscillator 227 or other clock source. An off-chip crystal-based oscillator may refer to a crystal-based oscillator that is wholly or substantially implemented separate from the integrated circuit including the TCO 135. The crystal-based oscillator 227 may include one or more circuits to generate a reference periodic clock signal (e.g., f_{CAL}) used to perform an initial frequency correction procedure to compensate, for example, for process variations of the first oscillator 210 and/or the second oscillator 221. In some implementations, a switch 225 may selectively couple the reference periodic clock signal f_{CAL} to the temperature compensation block 220. In some example implementations, the initial frequency correction procedure also may determine an initial compensation value M₀. For example, the modulus generator 222 may compare the first oscillator output signal f_{REF} with the crystal-based oscillator 227 output signal (f_{CAL}) to determine the initial compensation value M₀. The crystal-based oscillator 227 may advantageously provide a reference signal (f_{CAL}) that is not dependent on temperature. Thus, the signal f_{CAL} may be used at any time or temperature to determine the initial compensation value M₀. The initial frequency correction procedure is described in more detail below in conjunction with FIGS. 3A, 3B, 4A, and 4B.

Persons skilled in the art will appreciate that a clock period may be related to a clock frequency by its reciprocal. Thus, the first oscillator 210, the second oscillator 221, and the TCO output signal may be described by a period instead of a frequency. In such cases, an output period of the TCO 135 (p_{OUT}) may be expressed as a period of the first oscillator 210 (p_{REF}) divided by the compensation value M.

$${p}_{OUT} = \frac{{p}_{REF}}{M} \qquad ( eq . 2 )$$

Equation 1 may be used to determine the output frequency of the TCO 135 when the frequencies of the first oscillator 210 and the second oscillator 221 vary linearly with temperature. In a similar manner, equation 2 may be used to determine the output period of the TCO 135 when the periods of the first oscillator 210 and the second oscillator 221 vary linearly with temperature.

FIG. 3A shows graph 300 depicting example temperature-frequency relationships of the first oscillator 210 and the second oscillator 221 of FIG. 2. Persons skilled in the art will recognize that the first oscillator 210 and the second oscillator 221 may have other operating frequencies and temperature-frequency relationships not shown in FIG. 3A. In addition, the graph 300 may aid in illustrating some general operating principles of the TCO 135 of FIGS. 1 and 2.

The temperature-frequency relationship of the first oscillator 210 is shown with a temperature dependence curve 301 which shows a first temperature-dependent frequency relationship between temperature and output frequency of the first oscillator 210. Two possible temperatures and frequencies illustrated by the temperature dependence curve 301 are shown below in Table 1:

TABLE 1

| Temperature | Frequency |
|---|---|
| T₀ | 1.00 MHz |
| T₁ | 1.10 MHz |

Other temperature/frequency combinations are possible but are not listed in Table 1 for simplicity.

Similarly, the temperature-frequency relationship of the second oscillator 221 is shown with a temperature dependence curve 302 which shows a second temperature-dependent frequency relationship between temperature and output frequency of the second oscillator 221. Two possible temperatures and frequencies illustrated by the temperature dependence curve 302 are shown below in Table 2:

TABLE 2

| Temperature | Frequency |
|---|---|
| T₀ | 1.00 MHz |
| T₁ | 10 MHz |

Other temperature/frequency combinations are possible but are not listed in Table 2 for simplicity.

While the first oscillator 210 and the second oscillator 221 may both be temperature-dependent oscillators, the temperature-frequency relationship of each oscillator may be different from each other. For example, as shown in FIG. 3A, since the temperature dependence curve 301 is flatter (e.g., has a smaller slope) than the temperature dependence curve 302, the first oscillator 210 may be less temperature-dependent than the second oscillator 221. In other implementations, the temperature dependence curve 301 may be steeper (e.g., have a greater slope) than the temperature dependence curve 302, and thus the first oscillator 210 may be more temperature-dependent than the second oscillator 221. When the temperature dependence of each oscillator is different (e.g., the slopes of the temperature dependence curves are different), the ratio of the output frequencies of the first oscillator 210 and the second oscillator 221 may be easier to determine since the absolute frequencies associated with each oscillator may vary differently with temperature. The ratio of oscillator output frequencies may be used to generate a temperature compensation signal, as discussed below with respect to the compensation value M in equation 4.

In some implementations, the temperature dependence of an oscillator may be controlled or affected by oscillator circuit design, component selection, substrate doping concentrations and the like. Further, in the example of FIG. 3A, the temperature dependence curves 301 and 302 are shown as converging toward a common frequency at temperature T₀ for convenience. In other implementations, the temperature dependence curves 301 and 302 may intersect at other temperatures or may not intersect at all (e.g., there may be no common frequency) within an operating temperature range of interest. Likewise, although the common frequency is shown associated with temperature T₀, the common frequency (if any common frequencies exist) may be associated with any temperature. The temperature dependence of the first oscillator 210 and the second oscillator 221 (and therefore the temperature dependence curves 301 and 302) may be determined by bench testing and/or simulation. Thus, the temperature dependence curves 301 and 302 may be known prior to operation of the TCO 135.

Operation of the modulus generator 222 may be based on an initial gain factor K_{INIT}, a ratio r of oscillator output frequencies, and an initial frequency correction procedure to determine the initial compensation value M₀. A gain factor K is said to refer to a relative slope between the temperature dependence curve 301 and the temperature dependence curve 302. Thus, K_{INIT} may be a first or initial value of the gain factor K. In some implementations, the initial compensation value M₀ may be associated with the initial gain factor K_{INIT} and a first determination of the ratio r. Further, the initial gain factor K_{INIT}, based on the temperature dependence curves 301 and 302, may be determined prior to operation of the TCO 135.

In one example implementation, the initial gain factor K_{INIT} may be determined based on one or more operating points of the first oscillator 210 and the second oscillator 221 associated with the temperature dependence curves 301 and 302 as expressed by the equation below:

$${K}_{INIT} = \frac{{f}_{TS 1} - {f}_{TS 0}}{{f}_{REF 1} - {f}_{REF 0}} \qquad ( eq . 3 )$$

Where: f_{TS0} is a first frequency associated with the second oscillator 221 (for example, temperature dependence curve 302 at temperature=T₀);
   f_{TS1} is a second frequency associated with the second oscillator 221 (for example, temperature dependence curve 302 at temperature=T₁);
   f_{REF0} is a first frequency associated with the first oscillator 210 (for example, temperature dependence curve 301 at temperature=T₀); and
   f_{REF1} is a second frequency associated with the first oscillator 210 (for example, temperature dependence curve 301 at temperature=T₁);
   where T₁>T₀.
      In other words, the initial gain factor K_{INIT}, which may be equivalent to a relative slope, may be determined based on the output frequencies of each oscillator at two different temperatures. To illustrate with a numerical example using equation 3, if f_{TS0}=1 MHz, f_{TS1}=10 MHz, f_{REF0}=1 MHz, and f_{REF1}=1.10 MHz, then K_{INIT} may be approximately 90.

For simplicity, the temperature dependence curves 301 and 302 of example of FIG. 3A are shown as having a constant slope for all temperatures. However, since the free-running behavior of the first oscillator 210 and the second oscillator 221 may vary differently within different temperature ranges, common temperatures T₀ and T₁ are used to determine first and second frequencies for both the first oscillator 210 and the second oscillator 221 in equation 3.

The ratio r may provide a relative measure (e.g., a ratio) of output frequencies of the first oscillator 210 and the second oscillator 221. The graph 300 shows a one-to-one mapping between temperature (T) and oscillator output frequencies. For example, a first ratio R₀ may be associated with temperature T₀ and a second ratio R₁ may be associated with temperature T₁. Note that in the example of FIG. 3A, R₀=1 and R₁=9.09. Due to the different temperature dependence of each oscillator, a unique oscillator output frequency ratio r may be associated with a unique temperature T. Looked at another way, a unique ratio r may be associated with a unique frequency drift associated with each oscillator.

In one implementation, the ratio r may be determined with a counter. The counter may provide a relative ratio of a first oscillator output signal with respect to a second oscillator output signal. For example, a counter may be configured to count clock cycles of the first oscillator for a duration of time determined by a clock period of the second oscillator. Thus, in one embodiment, the ratio r may be the number of clock cycles of the second oscillator 211 (f_{TS}) counted during a clock period of the first oscillator 210 (f_{REF}). In another example, the ratio r may be the number of clock cycles of the first oscillator 210 (f_{REF}) during a clock period of the second oscillator 221 (f_{TS}). The ratio r of the output signal of the second oscillator 211 with respect to the output signal of the first oscillator 210 may be denoted as r=f_{TS}/f_{REF}.

An initial frequency correction procedure using a signal with a known frequency may be used to determine the initial compensation value M₀. To illustrate with an example, a target output frequency f_{OUT} of the TCO 135 may be 10 MHz and the first oscillator 210 may have an initial output frequency of f_{REF0}=1 MHz. As discussed above with respect to equation 1, the output of the TCO 135 may be expressed as f_{OUT}=f_{REF}*the compensation value M. During the initial frequency correction procedure, the known frequency (f_{CAL}) from the crystal-based oscillator 227 may be received by the modulus generator 222. The modulus generator 222 can determine the initial compensation value M₀ by determining a relative ratio of the output signal of the first oscillator f_{REF} with respect to the output signal of the crystal-based oscillator f_{CAL}. Similar to as described above for determining the ratio r, a counter may count clock cycles of the first oscillator 210 (f_{REF}) during a clock period of the crystal-based oscillator 227 (f_{CAL}) to determine a first-oscillator-to-crystal-based reference ratio N₀. The signal f_{REF0} denotes the output signal of the first oscillator 210 when the first-oscillator-to-crystal-based reference ratio N₀ is determined.

The initial frequency correction procedure may occur during a first time period, while normal operation may occur during a second time period. In some embodiments, the first time period may be associated with a first powering-on of the TCO 135 and performing the initial correction procedure while the second time period may be associated with operating the TCO 135 any time after the initial correction procedure. Thus, the crystal-based oscillator 227 may be coupled to the modulus generator 222 during the first time period to determine the first-oscillator-to-crystal-based reference ratio N₀, and may be isolated from the modulus generator 222 during the second time period. If the frequency of the first oscillator 210 at this time is f_{REF0} and the frequency of the crystal-based oscillator is f_{CAL}, then the first-oscillator-to-crystal-based reference ratio value N₀ may be denoted N₀=f_{REF0}/f_{CAL}.

In addition, a ratio R₀ may be determined when the first-oscillator-to-crystal-based reference ratio N₀ is determined. In some implementations, the ratio R₀ may be the ratio of the output of the second oscillator 221 with respect to the output of the first oscillator 210. For example, a counter may count clock cycles of the second oscillator 221 during a clock period of the first oscillator 210. If the frequency of the first oscillator at this time is f_{REF0} and the frequency of the second oscillator at this time is f_{TS0}, then the ratio R₀ may be denoted R₀=f_{TS0}/f_{REF0} and may be determined by a counter as described above for the ratio r.

The compensation value M may be determined as expressed by the equation below:

$$Compensation Value M = \frac{K - r}{K - {R}_{0}} * ( 1 / {N}_{0} ) \qquad ( eq . 4 )$$

Where: r is the ratio of the output of the second oscillator with respect to the output of the first oscillator;
   R₀ is the ratio of the output of the second oscillator with respect to the output of the first oscillator when N₀ is determined; and
   N₀ is the first-oscillator-to-crystal-based reference ratio.
      Note that when K=K_{INIT}, and the ratio r=R₀, then equation 4 may determine the initial compensation value M₀ associated with the initial correction procedure. Notably, equation 4 may be simplified, showing that the initial compensation value M₀ may be related to the first-oscillator-to-crystal-based reference ratio N₀ (e.g., M₀=(1/N₀)).

Furthermore, the compensation value M as expressed by equation 4 may be used to compensate for temperature drift during operation of the TCO 135. That is, equation 4 may be used to determine an updated compensation value M for the TCO 135 after the initial frequency correction procedure. Only the ratio r value needs to be updated after the initial frequency correction procedure. The relationship between N₀, P₀, R₀, r, N₁, P₁ and the gain factor K is discussed in more detail below in conjunction with FIGS. 4A and 4B.

Although the slope of the temperature dependence curves 301 and 302 are depicted as linear, in some implementations, the temperature-frequency relationship of the first oscillator 210 and the second oscillator 221 (and therefore the slope of the temperature dependence curves associated with the first oscillator 210 and the second oscillator 220) may be piecewise linear or non-linear. In some cases, the gain factor K may be determined multiple times, for example, at least once for each piecewise linear section of the temperature dependence curves. An example piecewise linear temperature-frequency relationship is discussed below in conjunction with FIG. 3B.

FIG. 3B shows a graph 350 depicting other example temperature-frequency relationships of the first oscillator 210 and the second oscillator 221 of FIG. 2. The temperature-frequency relationship of the first oscillator 210 is shown with a temperature dependence curve 351 and the temperature-frequency relationship of the second oscillator 221 is shown with a temperature dependence curve 352. Between the temperatures T_{A} and T_{B}, the first oscillator 210 and the second oscillator 221 may each have a first linear temperature-frequency relationship. Between the temperatures T_{B} and T_{C}, the first oscillator 210 and the second oscillator 221 may each have a second linear temperature-frequency relationship. Thus, the temperature-frequency relationships may be piecewise linear between the temperatures T_{A} and T_{B} and between T_{B} and T_{C}. Although only two temperature ranges are shown in the example graph 350 (e.g., T_{A}−T_{B} and T_{B}−T_{C}), in other implementations, any number of temperature ranges, and therefore any number of piecewise linear temperature relationships, are possible.

In some implementations, the gain factor K may be updated at different temperatures to accommodate the piecewise linear temperature-frequency relationships of the first oscillator 210 and the second oscillator 211. For example, an updated gain factor K (different from K_{INIT}) may be referred to as K_{CALC} and may be expressed by the equation below:

$${K}_{CALC} = \frac{{P}_{1} - {P}_{0}}{{N}_{1} - {N}_{0}} \qquad ( eq . 5 )$$

Where: P₀ is a ratio of the output of the second oscillator 221 to the output of the crystal-based oscillator at temperature T_{B};
   P₁ is a ratio of the output of the second oscillator 221 to the output of the crystal-based oscillator at temperature T_{C};
   N₀ is a first-oscillator-to-crystal-based reference ratio at temperature T_{B}; and
   N₁ is a first-oscillator-to-crystal-based reference ratio at temperature T_{C}.
      Note that for the purposes of determining K_{CALC} in equation 5, T_{B} may represent any first temperature and T_{C} may represent any second temperature. The temperatures T_{B} and T_{C} were selected merely to illustrate possible points on the temperature dependence curves 351 and 352 and are not meant to be limiting.

P₀ may be a ratio of a frequency of the output of the second oscillator 221 with respect to a frequency of the output of the crystal-based oscillator 2270 at the temperature T_{B}. In some example implementations, if the frequency of the second oscillator 211 at the temperature T_{B} is denoted f_{TS-B}, then P₀ may be determined by a counter counting clock cycles of the second oscillator 211 (f_{TS-B}) during a clock period of the crystal-based oscillator 227 (f_{CAL}). If the frequency of the second oscillator 211 at a second temperature T_{C} is f_{TS-C}, then P₁ may be determined by a counter counting clock cycles of the second oscillator 211 (f_{TS-C}) during a clock period of the crystal-based oscillator 227 (f_{CAL}). Similarly, if the frequency of the output of the first oscillator 210 at the temperature T_{B} is f_{REF-B}, then the first-oscillator-to-crystal-based N₁ may be determined by a counter counting clock cycles of the first oscillator (f_{REF-B}) during a clock period of the crystal-based oscillator (f_{CAL}).

The gain factor K_{CALC} may be determined any number of times to improve the performance of the TCO 135. For example, the gain factor K_{CALC} may be determined with respect to different temperature ranges to accommodate the piecewise linear or non-linear temperature dependence of the first oscillator 210 and the second oscillator 221. In some implementations, the output frequency of the first oscillator 210 and/or the second oscillator 221 may change (e.g., drift) due to operating voltage or other operating conditions. Determining the gain factor K_{CALC} may help correct for changes in operating conditions. Notably, continuous operation of the crystal-based oscillator 227 is not required. Operation of the crystal-based oscillator 227 is only necessary to perform the initial frequency correction procedure and during any optional update of the gain factor K_{CALC}. After the initial correction procedure or after the determination of the gain factor K_{CALC}, the crystal-based oscillator 227 may be powered down. The relationship of the gain factor K_{CALC} and N₀, P₀, R₀, r, N₁, P₁, and the gain factor K_{INIT} is discussed in more detail below in conjunction with FIGS. 4A and 4B.

As described above, the outputs of the first oscillator 210, the second oscillator 221, and the TCO 135 may be described in terms of periods instead of frequency. Thus, in some implementations, persons skilled in the art will recognize that K_{INIT}, K_{CALC}, and the compensation value M may be determined in a manner similar to as described above with respect to equations 3-5 by bearing in mind the reciprocal relationship between frequency and period.

FIG. 4A is a block diagram of one embodiment of a modulus generator 400. The modulus generator 400 may be an implementation of the modulus generator 222 of FIG. 2. The modulus generator 400 may generate the compensation value M for temperature-dependent oscillators whose output frequencies vary linearly with respect to temperature. The modulus generator 400 may receive the output signal from the first oscillator 210 (f_{REF}), the output signal from the second oscillator 221 (f_{TS}), the output signal from the crystal-based oscillator 227 (f_{CAL}) and may generate the compensation value M. The modulus generator 400 may include counters 401-406, a first computation block 410, a second computation block 420, a K_{INIT} storage register 425, a selector 430, a scale factor storage register 435 and a multiplier 440.

The counters 401-406 may be used to determine values of one or more parameters used to determine the compensation value M as described with respect to the equations 3-5 above. The counter 401 may determine the first-oscillator-to-crystal-based reference ratio N₀. The counter 401 may receive the f_{REF} signal and the f_{CAL} signal and may generate the first-oscillator-to-crystal-based reference ratio N₀ by, for example, counting a number of clock cycles of f_{REF} during a period of f_{CAL}. The f_{REF} signal is referred to as f_{REF0} to denote that the frequency of the first oscillator 210 may be associated with the initial correction procedure occurring at an initial temperature T₀.

The counter 402 may determine the ratio P₀. The counter 402 may receive the f_{TS} signal and the f_{CAL} signal and may generate the ratio P₀ by, for example, counting a number of clock cycles of f_{TS} during a period of f_{CAL}. The f_{TS} signal is referred to as f_{TS0} to denote that frequency of the second oscillator 221 may be associated with the initial correction procedure occurring at the temperature T₀.

The counter 403 may determine the ratio R₀. The counter 403 may receive the f_{REF} signal and the f_{TS} signal and may generate the ratio R₀ by, for example, counting a number of clock cycles of f_{TS} during a period of f_{REF}. The f_{TS} and the f_{REF} signals are referred to as f_{TS0} and f_{REF0} for reasons noted above. The counters 401-403 may be associated with the initial correction procedure.

The counter 404 may determine a ratio r. The counter 404 may receive the f_{REF} signal and the f_{TS} signal and may generate the ratio r by, for example, counting a number of clock cycles of f_{TS} during a period of f_{REF}.

The counter 405 may determine a first-oscillator-to-crystal-based reference ratio value N₁. The counter 405 may receive the f_{REF} signal and the f_{CAL} signal and may generate the first-oscillator-to-crystal-based reference ratio value N₁ by, for example, counting a number of clock cycles of f_{REF} during a period of f_{CAL}. The f_{REF} signal is referred to as f_{REF1} to denote that the frequency of the first oscillator 210 may be associated with an optional gain factor update procedure occurring at a temperature T₁.

The counter 406 may determine the ratio P₁. The counter 406 may receive the f_{TS} signal and the f_{CAL} signal and may generate the ratio P₁ by, for example, counting a number of clock cycles of f_{TS} during a period of f_{CAL}. The f_{TS} signal is referred to as f_{TS1} to denote that the frequency of the second oscillator 221 may be associated with the optional gain factor update procedure occurring at the temperature T₁

Six separate counters 401-406 are shown within the modulus generator 400 to ease explanation. In some implementations, the output of some of the counters may be stored in a register and the associated counter may be reused. For example, the counter 401 may generate the first-oscillator-to-crystal-based reference ratio N₀. The first-oscillator-to-crystal-based reference ratio N₀ may be stored and the counter 401 may be reused to operate as the counter 405 to generate the first-oscillator-to-crystal-based reference ratio N₁. Persons skilled in the art will appreciate that other counter reuses are possible, and that additional counters may be used in some implementations. Thus, fewer than six (e.g., 1-5) counters may be implemented or more than six counters may be implemented.

The first computation block 410 may be configured to implement equation 4, as described above. The value of K for the first computation block 410 may be provided by the selector 430. The selector 430 may select between K_{INIT} stored in K_{INIT} storage register 425 and the second computation block 420. The K_{INIT} value may be determined before operation of the modulus generator 400 in accordance with equation 3 described above. The second computation block 420 may be configured to implement equation 5 to determine the gain factor K, denoted as K_{CALC} herein. The output of the first computation block 410 may be scaled by an optional scale factor S provided by the scale factor storage register 435 through the multiplier 440. In some embodiments, the scaling provided by the multiplier 440 and the scale factor S may be optional. The scale factor S may be used to increase or decrease the value of the compensation value M that may be provided to the output block 230 of FIG. 2. For example, in some implementations, the output block 230 may expect a particular magnitude of the compensation value M. The multiplier 440 may enable scaling of the compensation value M before being received by the output block 230. In some implementations, functionality of the multiplier 440 may be included within the output block 230.

FIG. 4B is a block diagram of another embodiment of a modulus generator 450. The modulus generator 450 may be another implementation of the modulus generator 222 of FIG. 2. In contrast to the modulus generator 400 of FIG. 4A, the modulus generator 450 may generate the compensation value M for temperature-dependent oscillators whose output periods vary linearly with respect to temperature. Clock periods have a reciprocal relationship to clock frequency, so many of the equations of FIG. 4B have a reciprocal relationship to equations of FIG. 4A. The modulus generator 450 may receive the output signal from the first oscillator 210 (f_{REF}), the output signal from the second oscillator 221 (f_{TS}), and the output signal from the crystal-based oscillator 227 (f_{CAL}) and may generate the compensation value M. The modulus generator 450 may include counters 451-456, a third computation block 460, the second computation block 420, the K_{INIT} storage register 425, the selector 430, the scale factor storage register 435 and the multiplier 440. The second computation block 420, the K_{INIT} storage register 425, the selector 430, the scale factor storage register 435 and the multiplier 440 may be similar to the similarly named and numbered elements of FIG. 4A.

The counters 451-456 may be used to determine values of one or more parameters used to determine the compensation value M as described with respect to the equations 3-5 above. Notably, since periods are the reciprocal of frequency, the parameters described with respect to FIG. 4B may be related by a reciprocal to similar parameters in FIG. 4A. Further, a reciprocal of equation 4 may be used to determine the compensation value M. The counter 451 may determine the first-oscillator-to-crystal-based reference ratio N₀. The counter 451 may receive the f_{REF} signal and the f_{CAL} signal and may generate the first-oscillator-to-crystal-based reference ratio N₀ by, for example, counting a number of clock cycles of f_{CAL} during a period of f_{REF}. The f_{REF} signal is referred to as f_{REF0} as described above with respect to FIG. 4A.

The counter 452 may determine the ratio P₀. The counter 452 may receive the f_{TS} signal and the f_{CAL} signal and may generate the ratio P₀ by, for example, counting a number of clock cycles of f_{CAL} during a period of f_{TS}. The f_{TS} signal is referred to as f_{TS0} as described above with respect to FIG. 4A.

The counter 453 may determine the ratio R₀. The counter 453 may receive the f_{REF} signal and the f_{TS} signal and may generate the ratio R₀ by, for example, counting a number of clock cycles of f_{REF} during a period of f_{TS}. The f_{TS} and the f_{REF} signals are referred to as f_{TS0} and f_{REF0} as described above with respect to FIG. 4A. The counters 451-453 may be associated with the initial correction procedure.

The counter 454 may determine the ratio r. The counter 454 may receive the f_{REF} signal and the f_{TS} signal and may generate the ratio r by, for example, counting a number of clock cycles of f_{REF} during a period of f_{TS}.

The counter 455 may determine the first-oscillator-to-crystal-based crystal-based reference ratio N₁. The counter 455 may receive the f_{REF} signal and the f_{CAL} signal and may generate the first-oscillator-to-crystal-based reference ratio N₁ by, for example, counting a number of clock cycles of f_{CAL} during a period of f_{REF}. The f_{REF} signal is referred to as f_{REF1} as described above with respect to FIG. 4A.

The counter 456 may determine a ratio P₁. The counter 456 may receive the f_{TS} signal and the f_{CAL} signal and may generate the ratio P₁ by, for example, counting a number of clock cycles of f_{CAL} during a period of f_{TS}. The f_{TS} signal is referred to as f_{TS1} as described above with respect to FIG. 4A. Similar to how FIG. 4A was described, fewer than six (e.g., 1-5) counters may be implemented or more than six counters may be implemented pursuant to the embodiment described in FIG. 4B.

The third computation block 460 may function similarly to the first computation block 410 described with respect to FIG. 4A. In some embodiments, the third computation block 460 may implement a reciprocal of equation 4 as expressed below in equation 6:

$$Compensation Value M = \frac{K - {R}_{0}}{K - r} * ( {N}_{0} ) \qquad eq . 6$$

Based on equation 6, an initial compensation value M₀ may be defined as the compensation value M determined when N₀ is determined. Because r=R₀ when N₀ is determined, equation 6 may be simplified, showing that the initial compensation value M₀ may be related to the first-oscillator-to-crystal-based reference ratio N₀ (e.g., M₀=(N₀)). Notably, the compensation value M of equation 6 may be easier to compute than the compensation value M of equation 5 since equation 6 lacks a division operation included in equation 5. Thus, in some implementations, the operations associated with FIG. 4B may be simpler to implement than the operations associated with the FIG. 4A. In other implementations, the operations associated with the FIG. 4A may be simpler to implement than the operations associated with the FIG. 4B.

The second computation block 420, the K_{INIT} storage register 425, the selector 430, the scale factor storage register 435, and the multiplier 440 may operate as described above with respect to FIG. 4A.

FIG. 5 is a block diagram of one embodiment of an output block 500. The output block 500 may be an implementation of the output block 230 of FIG. 2. In some implementations, the output block 500 may operate as a frequency-locked loop. The output block 500 may include a frequency detector 510, an adder 520, a digital loop filter 530, and a digitally controlled oscillator 550. The output block 500 may receive the output signal f_{REF} from the first oscillator 210, the compensation value M, and may generate the f_{OUT} signal for the TCO 135 of FIG. 2.

The frequency detector 510 may receive the f_{REF} signal and the f_{OUT} signal from the digitally controlled oscillator 550. The frequency detector 510 may generate a count based on the f_{REF} signal and the f_{OUT} signal. In one embodiment, the frequency detector 510 may count clock cycles of a first signal during a clock period of the second signal. For example, the frequency detector 510 may count clock cycles of the f_{REF} signal during a clock period of the f_{OUT} signal. In another example, the frequency detector 510 may count clock cycles of the f_{OUT} signal during a clock period of the f_{REF} signal.

The adder 520 may receive the compensation value M and the output of the frequency detector 510. In one implementation, the adder 520 may subtract the output of the frequency detector 510 from the compensation value M and generate an error signal. The error signal from the adder 520 may be provided to the digital loop filter 530. In some embodiments, the digital loop filter 530 may accumulate (e.g., add together) a number of the error signals and determine an accumulator value. Additionally, the digital loop filter 530 may encode the accumulator value for the digitally controlled oscillator 550. For example, the accumulator value may be in a conventional binary format, while the digitally controlled oscillator 550 may expect a thermometer encoded input. In this example, the digital loop filter 530 may convert (encode) the accumulator value from the conventional binary format to a thermometer format. Persons skilled in the art will recognize that the operations of the digital loop filter 230 described herein are exemplary and are not limiting. The digitally controlled oscillator 550 may generate the four signal based on a code from the digital loop filter 530.

Persons skilled in the art will appreciate that the example output block 500 is merely one possible implementation. Other implementations are possible. For example, while the example output block 500 may depict a digital implementation, in other implementations the output block 500 may include a substantially analog implementation (not shown for simplicity).

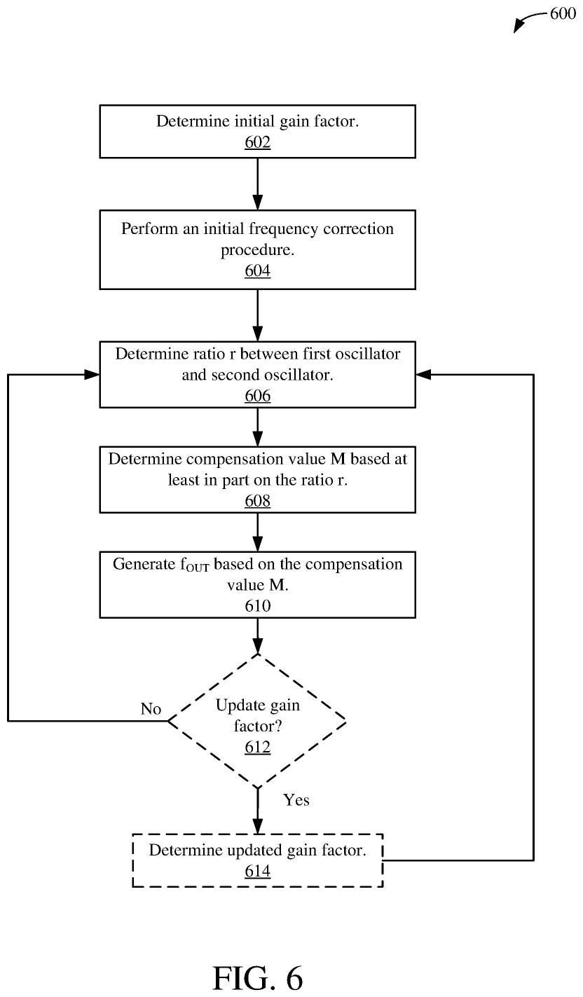

FIG. 6 is a flowchart depicting an example operation 600 for operating the TCO 135 of FIGS. 1 and 2. Although described herein as being performed by the wireless device 102 of FIG. 1, the operation 600 may be performed by the wireless device 103, or any other suitable device, processor, or controller. The operation begins as the wireless device 102 determines an initial gain factor K_{INIT} (602). The initial gain factor K_{INIT} may be determined by simulation and/or bench testing. In some implementations, the initial gain factor K_{INIT} may be determined as described above with respect to equation 3. Thus, frequencies or periods associated with the first oscillator (f_{REF0} and f_{REF1}) and frequencies or periods associated with the second oscillator (f_{TS0} and f_{TS1}) may be determined with any feasible counter, analyzer, monitor, or the like.

Next, the wireless device 102 may perform an initial frequency correction procedure (604). In some example implementations, the initial frequency correction procedure 604 may include operations for determining an initial compensation value M₀. For example, N₀, P₀, and R₀ values may be determined by using an off-chip crystal-based oscillator and the counters 401-403 of the modulus generator 400 or the counters 451-453 of the modulus generator 450. The initial compensation value M₀ may then be determined using the N₀, P₀, R₀, r (=R₀), and K_{INIT} values by the computation block 410 or 460 implementing equations 4 or 6, respectively. After performing the initial frequency correction procedure 604, use of the off-chip crystal-based oscillator may end and may be powered down.

Next, the wireless device 102 may determine the ratio r between the first oscillator 210 and the second oscillator 221 (606). In some implementations, the wireless device 102 may determine the ratio r using the counters 404 or 454 within the modulus generators 400 or 450, respectively. In one implementation, the ratio r may be determined by counting the number of clock cycles of the first oscillator 210 during a clock period of the second oscillator 221. In another implementation, the ratio r may be determined by counting the number of clock cycles of the second oscillator 221 during a clock period of the first oscillator 210.

Next, the wireless device 102 may determine a compensation value M based at least in part on the ratio r (608). In some implementations, the wireless device 102 may use the ratio r determined in 606. In addition, the compensation value M also may be determined using the gain factor of K_{INIT} or K_{CALC} and a computation block implementing equation 4 or 6 of the modulus generator 400 or the modulus generator 450, respectively. If K_{CALC} has not been determined (see 612 and 614 below), then the compensation value M may be determined based on the initial gain factor K_{INIT}.

Next, the wireless device 102 may generate the output signal f_{OUT} based at least in part on the compensation value M (610). In some implementations, the compensation value M may be received by the output block 230 of FIG. 2 or the output block 500 of FIG. 5. The output blocks 230 and/or 500 may generate the output signal f_{OUT} based on the first oscillator output f_{REF} and the compensation value M. In some implementations, the frequency of the output signal f_{OUT} may be based on a frequency of the first oscillator 210 multiplied by the compensation value M.

Next, the wireless device 102 may determine if the gain factor K should be updated (612). In some implementations, the wireless device 102 may update the gain factor K for any number of reasons. For example, the gain factor K may be updated when the ratio r (as determined in 608) is greater than a first threshold or when the determined compensation value M is greater than a second threshold. In another example, the gain factor K may be updated periodically. If the gain factor K is not to be updated, then the operation returns to 606.

On the other hand, if the gain factor K is to be updated (614), then, in some implementations, the gain factor K_{CALC} may be determined as described above with respect to equation 5. The operation then returns to 606. The operations 612 and 614 are optional and therefore are depicted with dashed lines. Updating the gain factor K may provide better frequency correction over different temperature ranges. However, in some implementations, reliance on the initial gain factor K_{INIT} (determined in 602) and the initial frequency correction procedure (in 604) may enable the TCO 135 to have adequate performance for some applications.

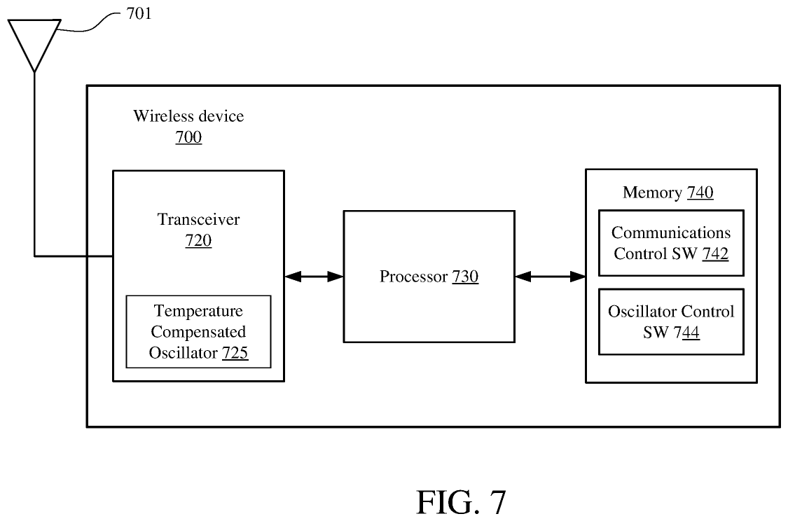

FIG. 7 shows a block diagram of an example wireless device 700. The example wireless device 700 may be an implementation of the wireless device 102 or the wireless device 103 of FIG. 1. The wireless device 700 may include antenna 701, one or more transceivers 720, a processor 730, and a memory 740. Although only one antenna 701 and one transceiver 720 are shown, the wireless device 700 may include any feasible number of antennas and/or transceivers (not shown for simplicity). The transceiver 720 may include a temperature-compensated oscillator (TCO) 725. In some implementations, the TCO 725 may be one implementation of the TCO 135 of FIGS. 1 and/or 2. The transceiver 720 may use a four signal provided by the TCO 725 (not shown for simplicity) to transmit or receive communication signals.

The memory 740 may include a non-transitory computer-readable storage medium (such as one or more nonvolatile memory elements, such as EPROM, EEPROM, Flash memory, a hard drive, and so on) that may store the following software modules:
a communication control software (SW) module 742 to control wireless transmission and reception operations of the wireless device 700; and
an oscillator control SW module 744 to control operations of the TCO 725, for example, as described above with respect to FIGS. 2-6.

The processor 730, which may be coupled to the transceiver 720 and the memory 740 may be any one or more suitable controllers or processors or the like capable of executing scripts or instructions of one or more software programs stored in the wireless device 700 (e.g., within the memory 740). In some embodiments, the processor 730 may be implemented with a hardware controller, a processor, a state machine or any other circuits to provide the functionality of the processor 730 executing instructions stored in the memory 740.

The processor 730 may execute the communications control SW module 742 to transmit and receive data via the transceiver 720. In some implementations, execution of the communications control SW module 742 may allow the wireless device 700 to transmit and receive wireless messages, beacons, and the like. For example, execution of the communications control SW module 742 may enable transmission and/or reception of Bluetooth, BLE, Wi-Fi, LTE or any other feasible wireless communication signals.

The processor 730 may execute the oscillator control SW module 744 to control operation of the TCO 725. In some implementations, execution of the oscillator control SW module 744 may allow the wireless device 700 to determine the gain factors K_{INIT}, K_{CALC}, the ratio R₀, the ratio r, parameters N₀, N₁, P₀, P₁, or any other feasible parameter or value as described above with respect to FIGS. 3, 4A and/or 4B. For example, execution of the oscillator control SW module 744 may determine a number of clock cycles of a free-running temperature-dependent oscillator occurring during a clock period of a crystal-based based oscillator output signal to determine N₀, P₀, N₁, or P₁. Execution of the oscillator control SW module 744 may also determine K_{CALC} in accordance with equation 5 and/or the second computation block 420.

The various illustrative logics, logical blocks, modules, and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some example implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those of ordinary skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

What is claimed is:

1. A temperature-compensated oscillator, comprising:
a first on-chip oscillator configured to generate a first periodic clock signal;
a second on-chip oscillator configured to generate a second periodic clock signal; and
a temperature compensation block configured to generate a compensation signal based on the first periodic clock signal and the second periodic clock signal.

2. The temperature-compensated oscillator of claim 1, further comprising:
a switch configured to selectively couple an off-chip crystal-based oscillator to the temperature compensation block.

3. The temperature-compensated oscillator of claim 1, further comprising:
an output block configured to generate an oscillator output signal having a frequency based on a frequency of the first periodic clock signal multiplied by the compensation signal.

4. The temperature-compensated oscillator of claim 1, wherein the compensation signal is based on a ratio of the first periodic clock signal to the second periodic clock signal.

5. The temperature-compensated oscillator of claim 4, wherein the ratio is a ratio of a frequency of the first periodic clock signal to a frequency of the second periodic clock signal or a ratio of a period of the first periodic clock signal to a period of the second periodic clock signal.

6. The temperature-compensated oscillator of claim 4, wherein the ratio is based on a number of clock cycles of the first periodic clock signal occurring during a period of the second periodic clock signal.

7. The temperature-compensated oscillator of claim 1, wherein the first on-chip oscillator and the second on-chip oscillator are free-running, temperature-dependent oscillators.

8. The temperature-compensated oscillator of claim 7, wherein the first on-chip oscillator has a first temperature-frequency relationship, the second on-chip oscillator has a second temperature-frequency relationship, and the first temperature-frequency relationship is different from the second temperature-frequency relationship.

9. The temperature-compensated oscillator of claim 8, wherein the compensation signal is based on a relative slope of the first temperature-frequency relationship to the second temperature-frequency relationship.

10. A temperature-compensated oscillator, comprising:
means for generating a first periodic clock signal via a first on-chip oscillator;
means for generating a second periodic clock signal via a second on-chip oscillator; and
means for generating a compensation signal based on the first periodic clock signal and the second periodic clock signal.

11. The temperature-compensated oscillator of claim 10 further comprising:
means for selectively coupling an off-chip crystal-based oscillator to the means for generating the compensation signal.

12. The temperature-compensated oscillator of claim 10, further comprising:
means for generating an oscillator output signal having a frequency based on multiplying a frequency of the first periodic clock signal with the compensation signal.

13. The temperature-compensated oscillator of claim 10, wherein the compensation signal is based on a ratio of the first periodic clock signal to the second periodic clock signal.

14. The temperature-compensated oscillator of claim 13, wherein the ratio is based on a number of clock cycles of the first periodic clock signal occurring during a period of the second periodic clock signal.

15. The temperature-compensated oscillator of claim 10, wherein the first on-chip oscillator and the second on-chip oscillator are free-running, temperature-dependent oscillators.

16. The temperature-compensated oscillator of claim 15, wherein the first on-chip oscillator has a first temperature-frequency relationship, the second on-chip oscillator has a second temperature-frequency relationship, and the first temperature-frequency relationship is different from the second temperature-frequency relationship.

17. The temperature-compensated oscillator of claim 16, wherein the compensation signal is based on a relative slope of the first temperature-frequency relationship to the second temperature-frequency relationship.

18. A method comprising:
generating, by a first on-chip oscillator, a first periodic clock signal;
generating, by a second on-chip oscillator, a second periodic clock signal; and
generating, by a temperature compensation block, a compensation signal based on the first periodic clock signal and a second periodic clock signal.

19. The method of claim 18 further comprising:
coupling an off-chip crystal-based oscillator to the temperature compensation block during an initial frequency correction procedure; and
decoupling the off-chip crystal-based oscillator from the temperature compensation block after the initial frequency correction procedure.

20. The method of claim 18, further comprising:
generating an oscillator output signal having a frequency based on a frequency of the first periodic clock signal multiplied by the compensation signal.

21. The method of claim 18, wherein the first on-chip oscillator has a first temperature-frequency relationship, the second on-chip oscillator has a second temperature-frequency relationship, and the first temperature-frequency relationship is different from the second temperature-frequency relationship.

22. The method of claim 21, wherein the compensation signal is based on a relative slope of the first temperature-frequency relationship to the second temperature-frequency relationship.

23. The method of claim 18, wherein the compensation signal is based on a ratio of the first periodic clock signal to the second periodic clock signal.

24. The method of claim 23, wherein the ratio is based on a number of clock cycles of the first periodic clock signal occurring during a period of the second periodic clock signal.
